(19) United States
(12) Patent Application Publication
(10) Pub. No.: US 2025/0313993 A1
(43) Pub. Date: Oct. 9, 2025

(54) ULTRA-THIN SINGLE-CRYSTAL METAL FILM AND PREPARATION METHOD THEREOF

(71) Applicant: ZHEJIANG UNIVERSITY, Hangzhou (CN)

(72) Inventors: Pan Wang, Hangzhou (CN); Chenxinyu Pan, Hangzhou (CN); Jiajie Zhu, Hangzhou (CN); Limin Tong, Hangzhou (CN)

(21) Appl. No.: 19/245,257

(22) Filed: Jun. 21, 2025

Related U.S. Application Data
(63) Continuation of application No. PCT/CN2024/083090, filed on Mar. 21, 2024.

(30) Foreign Application Priority Data
Nov. 9, 2023 (CN) 202311489243.1

(51) Int. Cl. C30B 33/10; C30B 29/02

(52) U.S. Cl. CPC C30B 33/10; C30B 29/02

(57) ABSTRACT

Provided are an ultra-thin single-crystal metal film and a preparation method thereof. The single-crystal metal film has a thickness down to a single atomic layer, with a lateral dimension greater than 1 μm. In the present invention, a substrate with a single-crystal metal film grown thereon is placed in an etching solution for thinning by etching. Metal atoms are stripped layer by layer using strong interaction of chemical bonds between etching molecules and metal atoms. By setting a concentration of the etching solution to 5-500 mM and etching time to 5-900 min, atomic-level precision control over thickness of the single-crystal metal film can be realized, and the ultra-thin single-crystal metal film with a thickness down to a single atomic layer can be obtained. During the etching process, the lateral dimension of the single-crystal metal film remains essentially unchanged, enabling its lateral size even up to a meter scale.

### CROSS-REFERENCE TO RELATED APPLICATIONS

The present application is a continuation application of PCT application No. PCT/CN2024/083090 filed on Mar. 21, 2024, which claims the benefit of Chinese Patent Application No. 202311489243.1 filed on Nov. 9, 2023. The contents of all of the aforementioned applications are incorporated by reference herein in their entirety.

### TECHNICAL FIELD

The present invention relates to the field of ultra-thin metallic materials, and in particular to an ultra-thin single-crystal metal film with thickness controllable at atomic-level precision and a preparation method thereof.

### BACKGROUND

Low-dimensional single-crystal metallic materials (such as metal nanoparticles, metal nanowires, ultra-thin metal films, etc.) have attracted extensive research interest due to their unique physical, chemical, mechanical and other characteristics, and show important application prospects in the construction of nanoscale electronic and optoelectronic devices and the like. Ultra-thin (sub-10 nm scale in thickness) single-crystal metal film materials have advantages such as unique optoelectronic characteristics induced by quantum size effects, plasmon-enabled extreme light confinement, broadband and high infrared absorptivity, and high optical transmittance in visible spectral range. They are ideal candidates for realizing a new generation of ultra-thin electronic, photonic, and quantum devices based on metals.

The main methods for preparing metal films include physical vapor deposition (thermal evaporation, electron beam evaporation, etc.) and wet chemical synthesis. For physical vapor deposition methods, due to the poor wettability of metals on common dielectric substrates, when the thickness is less than 10 nm, the formed metal films usually exhibit an island-like discontinuous structure. The percolation threshold of metals can be significantly reduced using copper, organosilanes, etc. as seed layers or adhesion layers, thereby preparing large-area continuous ultra-thin metal films with a thickness down to 1-2 nm. However, the ultra-thin metal films obtained by such methods are polycrystalline structures, and the scattering loss of electrons at grain boundaries greatly affects their subsequent application performance. Meanwhile, due to the presence of seed layers or adhesion layers, the prepared ultra-thin metal films are difficult to be detached from the substrate, which greatly limits the multifunctional integration of ultra-thin metal films with other materials and structures.

Wet chemical synthesis methods (including seed-mediated synthesis, polymer reduction synthesis, two-dimensional template-assisted synthesis, methyl orange-assisted synthesis, etc.) can directly synthesize ultra-flat single-crystal metal sheets with a thickness of less than 1 nm. The reference “Ye, S. et al., Sub-Nanometer Thick Gold Nanosheets as Highly Efficient Catalysts. Adv. Sci. 6, 1900911, 2019” reports the synthesis of ultra-thin single-crystal gold sheets with a thickness of only 0.48 nm by a methyl orange-assisted method, but their lateral dimension is only about 100 nm. The current limitation of wet chemical synthesis methods is that during the synthesis of single-crystal metal sheets, the increase in their lateral dimensions is inevitably accompanied by an increase in thickness (despite differences in growth rates), which has so far made it still impossible to prepare large-size ultra-thin single-crystal metal sheets. For single-crystal metal sheets with a thickness of less than 5 nm, their lateral dimension is generally less than 1 μm, making it difficult to meet the application requirements in electronic and optoelectronic devices and the like.

Therefore, although ultra-thin single-crystal metal films have important application prospects in fundamental research and the construction of new-generation electronic, optoelectronic, and quantum devices, there is still no effective method to prepare ultra-thin large-size single-crystal metal films. In the present invention, a chemical etching-based thinning method is added, enabling the single-crystal metal film to achieve a thickness down to a single atomic layer while maintaining a large lateral dimension.

### SUMMARY

An objective of the present invention is to provide an ultra-thin single-crystal metal film and a preparation method thereof. By adopting this method, a readily available single-crystal metal film with a thickness greater than 10 nm can be thinned at atomic-level precision, thereby obtaining an ultra-thin single-crystal metal film with a thickness down to a single atomic layer.

The present invention discloses an ultra-thin single-crystal metal film and a preparation method thereof. The preparation method includes placing a thick initial single-crystal metal film grown on a substrate into an etching solution, achieving layer-by-layer stripping of the surface atoms of the metal film using reaction between the etching solution and metal atoms to ultimately obtain the ultra-thin single-crystal metal film with a thickness down to a single atomic layer.

To achieve the above objective, the technical solutions adopted in the present invention include the following steps:

The present invention discloses an ultra-thin single-crystal metal film, where the metal film has a thickness down to a single atomic layer, and a lateral dimension of the ultra-thin single-crystal metal film is greater than 1 μm.

As a further improvement, a material of the ultra-thin single-crystal metal film of the present invention is one of gold, silver, platinum, and copper.

As a further improvement, a surface roughness of the ultra-thin single-crystal metal film of the present invention is less than 1 nm.

The present invention discloses a method for preparing an ultra-thin single-crystal metal film, including steps of:
1) preparation of an initial single-crystal metal film 1: preparing a continuous single-crystal metal film on a substrate using epitaxial deposition, or preparing a large-size single-crystal metal sheet on a substrate using chemical synthesis, rinsing an obtained substrate with a single-crystal metal film grown thereon with deionized water, and drying with nitrogen for later use; and
2) preparation of an ultra-thin single-crystal metal film 2: placing the substrate with the single-crystal metal film grown thereon prepared in step 1) into an etching solution 3 for thinning by etching, so that a thickness of the single-crystal metal film gradually decreases with reaction time, after the thickness reaches a target thickness, taking out the substrate, and rinsing with deionized water, and drying with nitrogen to obtain the ultra-thin single-crystal metal film 2.

As a further improvement, the etching solution in step 2) of the present invention is one of a hydrogen peroxide solution, a cysteamine solution, and a cysteamine salt solution.

As a further improvement, the reaction time of the present invention is 5-900 min, and a concentration of the etching solution is 5-500 mM.

As a further improvement, the target thickness in step 2) of the present invention is 0.2-10 nm.

As a further improvement, a thickness of the initial single-crystal metal film 1 in step 1) of the present invention is greater than 10 nm.

As a further improvement, during the thinning by etching process of the present invention, thickness control of the single-crystal metal film is capable of reaching atomic-level precision.

Compared with the prior art, the beneficial effects of the present invention are as follows:
(1) in the present invention, the substrate with the single-crystal metal film grown thereon is placed in the etching solution for thinning by etching. Metal atoms are stripped layer by layer using strong interaction of chemical bonds between etching molecules and metal atoms, achieving an effect of thinning the single-crystal metal film;
(2) in the present invention, during the preparation process, by setting the concentration of the etching solution to 5-500 mM and the etching time to 5-900 min, atomic-level precision control over thickness of the single-crystal metal film can be realized, and the ultra-thin single-crystal metal film with a thickness down to a single atomic layer can be obtained;
(3) in the present invention, during the etching process, the lateral dimension of the single-crystal metal film remains essentially unchanged, enabling acquisition of the ultra-thin single-crystal metal film with the lateral dimension greater than 1 μm or even up to a meter scale. This significantly increases the lateral dimension of the ultra-thin metal film and expands an application scope of the material in fields such as optoelectronics;
(4) in the present invention, the surface roughness of the ultra-thin single-crystal metal film is less than 1 nm, featuring ultra-flat surface quality, which greatly reduces its optical loss;
(5) in the present invention, the thinning by etching method using the etching solution can more rapidly etch protrusions on the surface of the initial single-crystal metal film, so that the initial rough-surfaced single-crystal metal film can finally obtain ultra-flat surface quality, reducing the quality requirements for the initial single-crystal metal film; and
(6) in the present invention, the adopted chemical etching method is applicable to various metallic materials such as gold, silver, platinum, and copper, which greatly expands the range of ultra-thin single-crystal metals that can be prepared.

### BRIEF DESCRIPTION OF THE DRAWINGS

FIG. 1 shows photographs of single-crystal gold, silver, and copper sheets under an optical microscope in a transmission mode at different reaction times;

FIG. 2 shows an atomic force microscopy image of an ultra-thin single-crystal gold sheet with a thickness of 2.5 nm;

FIG. 3 is a selected area electron diffraction pattern of a surface of an ultra-thin single-crystal gold sheet with a thickness of 2.5 nm obtained by high-resolution transmission electron microscopy; and

FIG. 4 is a schematic diagram of a principle of chemical thinning by etching according to the present invention.

### DETAILED DESCRIPTION

The preparation process of the present invention is further described below in conjunction with the drawings. The specific process for preparing an ultra-thin single-crystal gold sheet by the chemical etching method in the present invention was as follows:

### Example 1

Step 1: a 1.5 cm×2 cm substrate was prepared, where the substrate material can be mica, silicon, silicon oxide, etc. The substrate was placed into acetone and ethanol each, ultrasonicated at a power of 100 W for 15 min, taken out, and dried with nitrogen for later use. 360 μl of 50 mM chloroauric acid aqueous solution was taken and mixed with 10 mL of ethylene glycol. Subsequently, the cleaned silicon wafer substrate was placed obliquely at the bottom of a clean capped glass bottle, and the mixed solution of chloroauric acid and ethylene glycol was injected into the bottle. After tightening the bottle cap, the bottle was placed in an oven at 95° C. for reaction for 5 h. After the reaction was completed, the substrate in the solution was taken out, rinsed repeatedly with deionized water, and then placed in ethanol for later use.

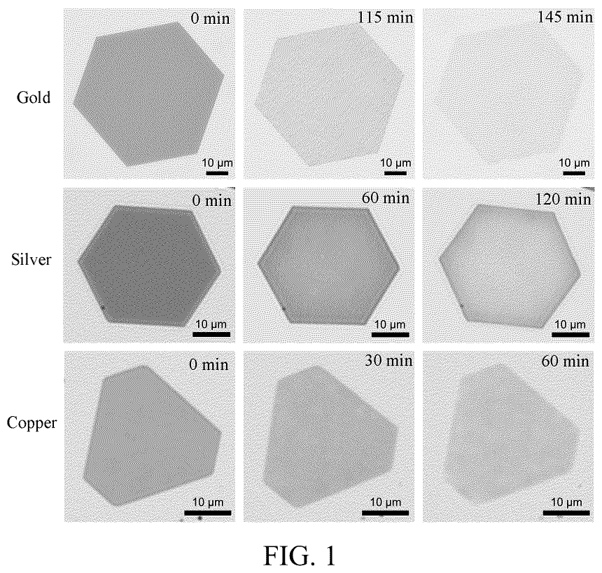

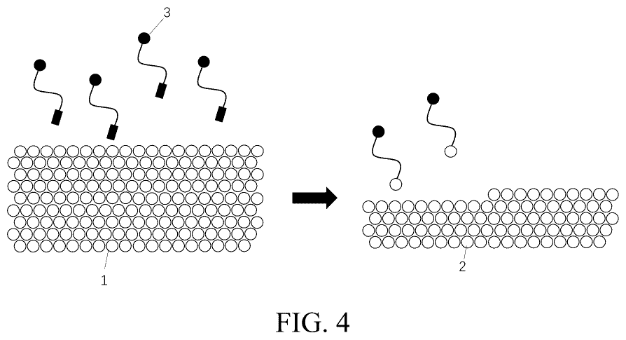

Step 2: a cysteamine solution with a concentration of 200 mM was prepared with chloroform as the solvent, and allowed to stand for 2 h for later use. The initial single-crystal gold sheet prepared in Step 1 was taken out of ethanol, dried with nitrogen, and then placed into a petri dish containing the cysteamine chloroform solution that had reacted for 2 h to start etching. The petri dish was placed under an optical microscope for monitoring of the etching process. With the progress of the chemical etching, the change in the color of the gold sheet under the transmission mode of the microscope is shown in FIG. 1 (the principle of chemical thinning by etching is shown in FIG. 4). When the color of the target gold sheet changed to the color corresponding to the target thickness under the microscope, the reaction was stopped. The silicon wafer was taken out and rinsed repeatedly with deionized water, and the ultra-thin single-crystal gold sheet was prepared, which can be stored in ethanol for a long time.

### Example 2

Step 1: a 1.5 cm×2 cm substrate was prepared, where the substrate material can be mica, silicon, silicon oxide, etc. The substrate was placed into acetone and ethanol each, ultrasonicated at a power of 100 W for 15 min, taken out, and dried with nitrogen for later use. 360 μl of 50 mM chloroauric acid aqueous solution was taken and mixed with 10 mL of ethylene glycol. Subsequently, the cleaned silicon wafer substrate was placed obliquely at the bottom of a clean capped glass bottle, and the mixed solution of chloroauric acid and ethylene glycol was injected into the bottle. After tightening the bottle cap, the bottle was placed in an oven at 95° C. for reaction for 5 h. After the reaction was completed, the substrate in the solution was taken out, rinsed repeatedly with deionized water, and then placed in ethanol for later use.

Step 2: a cysteamine solution with a concentration of 10 mM was prepared with chloroform as the solvent, and allowed to stand for 2 h for later use. The initial single-crystal gold sheet prepared in Step 1 was taken out of ethanol, dried with nitrogen, and then placed into a petri dish containing the cysteamine chloroform solution that had reacted for 2 h to start etching. The petri dish was placed under an optical microscope for monitoring of the etching process. With the progress of the chemical etching, the change in the color of the gold sheet under the transmission mode of the microscope is shown in FIG. 1. When the color of the target gold sheet changed to the color corresponding to the target thickness under the microscope, the reaction was stopped. The silicon wafer was taken out and rinsed repeatedly with deionized water, and the ultra-thin single-crystal gold sheet was prepared, which can be stored in ethanol for a long time.

### Example 3

Step 1: a 1.5 cm×2 cm substrate was prepared, where the substrate material can be mica, silicon, silicon oxide, etc. The substrate was placed into acetone and ethanol each, ultrasonicated at a power of 100 W for 15 min, taken out, and dried with nitrogen for later use. 360 μl of 50 mM chloroauric acid aqueous solution was taken and mixed with 10 mL of ethylene glycol. Subsequently, the cleaned silicon wafer substrate was placed obliquely at the bottom of a clean capped glass bottle, and the mixed solution of chloroauric acid and ethylene glycol was injected into the bottle. After tightening the bottle cap, the bottle was placed in an oven at 95° C. for reaction for 5 h. After the reaction was completed, the substrate in the solution was taken out, rinsed repeatedly with deionized water, and then placed in ethanol for later use.

Step 2: a cysteamine solution with a concentration of 400 mM was prepared with chloroform as the solvent, and allowed to stand for 2 h for later use. The initial single-crystal gold sheet prepared in Step 1 was taken out of ethanol, dried with nitrogen, and then placed into a petri dish containing the cysteamine chloroform solution that had reacted for 2 h to start etching. The petri dish was placed under an optical microscope for monitoring of the etching process. With the progress of the chemical etching, the change in the color of the gold sheet under the transmission mode of the microscope is shown in FIG. 1. When the color of the target gold sheet changed to the color corresponding to the target thickness under the microscope, the reaction was stopped. The silicon wafer was taken out and rinsed repeatedly with deionized water, and the ultra-thin single-crystal gold sheet was prepared, which can be stored in ethanol for a long time.

### Example 4

Step 1: a 1.5 cm×2 cm substrate was prepared, where the substrate material can be mica, silicon, silicon oxide, etc. The substrate was placed into acetone and ethanol each, ultrasonicated at a power of 100 W for 15 min, taken out, and dried with nitrogen for later use. 20 ml of deionized water and the cleaned glass slide substrate were placed in a clean capped glass bottle, and the bottle was then placed in a refrigerator at 8° C. for storage. 34 mg of silver nitrate powder was weighed and dissolved in 1 ml of deionized water to obtain a silver nitrate solution for later use. 34 mg of metol powder was weighed and dissolved in 10 ml of deionized water, and ultrasonicated for 10 min for complete dissolution to obtain a metol solution for later use. The refrigerated deionized water and glass slide were taken out. The glass slide was placed obliquely in the bottle. 200 μl of the silver nitrate solution was added, and after waiting for 10 s, 100 μl of the metol solution was added and allowed to stand for 1 min for reaction. After the reaction was completed, the glass slide substrate in the solution was taken out, rinsed repeatedly with deionized water, and then placed in ethanol for later use.

Step 2: a cysteamine solution with a concentration of 200 mM was prepared using dimethylformamide as the solvent, and allowed to stand for 2 h for later use. The initial single-crystal silver microsheet prepared in (1) was taken out of ethanol, dried with nitrogen, and then placed into a petri dish containing the cysteamine dimethylformamide solution that had reacted for 2 h to start etching. The petri dish was placed under an optical microscope for monitoring of the etching process. With the progress of the chemical etching, the change in the color of the silver sheet under the transmission mode of the microscope is shown in FIG. 1. When the color of the target silver sheet changed to the color corresponding to the target thickness under the microscope, the reaction was stopped. The glass slide was taken out and rinsed repeatedly with deionized water, and the ultra-thin single-crystal silver microsheet was prepared, which can be stored in ethanol for a long time.

### Example 5

Step 1: a 1.5 cm×2 cm substrate was prepared, where the substrate material can be mica, silicon, silicon oxide, etc. The substrate was placed into acetone and ethanol each, ultrasonicated at a power of 100 W for 15 min, taken out, and dried with nitrogen for later use. 2.4 g of copper chloride dihydrate, 3.9 g of glucose, 14.55 g of hexadecylamine, and 90 mg of sodium iodide were weighed and added to 900 ml of deionized water. The mixture was stirred simultaneously with a magnetic stir bar for 12 h to obtain a seed solution. Subsequently, 600 ml of the above seed solution was transferred to a clean container, the cleaned glass slide was placed into the container, which was then heated in a water bath at 100° C. for 12 h for reaction. After the reaction was completed, the glass slide substrate in the solution was taken out, rinsed repeatedly with deionized water, and then placed in ethanol for later use.

Step 2: a cysteamine solution with a concentration of 200 mM was prepared with chloroform as the solvent, and allowed to stand for 2 h for later use. The initial single-crystal copper microsheet prepared in (1) was taken out from ethanol, dried with nitrogen, and then placed into a petri dish containing the cysteamine chloroform solution that had reacted for 2 h to start etching. The petri dish was placed under an optical microscope for monitoring of the etching process. With the progress of the chemical etching, the change in the color of the copper sheet under the transmission mode of the microscope is shown in FIG. 1. When the color of the target copper sheet changed to the color corresponding to the target thickness under the microscope, the reaction was stopped. The glass slide was taken out and rinsed repeatedly with deionized water, and the ultra-thin single-crystal copper microsheet was prepared, which can be stored in ethanol for a long time.

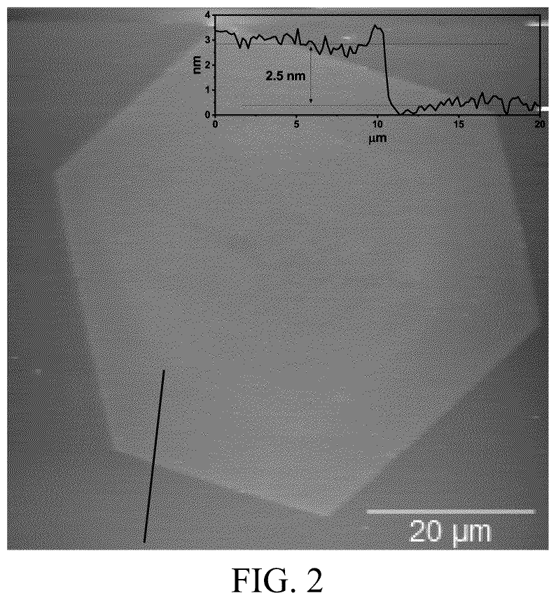

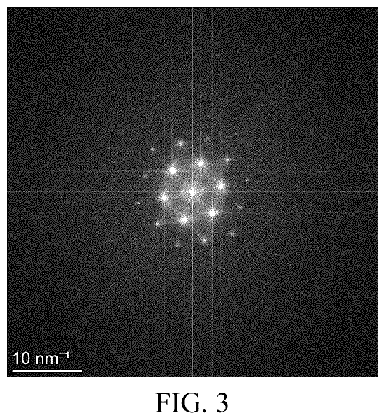

The prepared ultra-thin single-crystal gold sheet was characterized structurally, as shown in FIGS. 2 and 3: it exhibited a thickness of 2.5 nm, a surface roughness of less than 0.3 nm, atomic-level surface flatness, and a single-crystalline structure.

### Comparative Example 1

As the concentration of a cysteamine solution increased, the etching rate accelerated and the etching time shortened. However, when the concentration was too high, the reaction rate was too fast, leading to an increase in the surface roughness of the metal film; and when the concentration was too low, the reaction rate was too slow, resulting in excessively long etching time. Therefore, the concentration of the etching solution in the present invention is preferably 5-500 mM.

The ethylene glycol, chloroauric acid, and cysteamine powder adopted in this example were purchased from Sigma (USA), dimethylformamide was purchased from Shanghai Macklin Biochemical Co., Ltd., chloroform was purchased from Shanghai Sinopharm Chemical Reagent Co., Ltd., and deionized water was produced by the Milli-Q® Integral Water Purification System from Millipore.

The above implementation methods only describe the preferred embodiments of the present invention and do not limit the scope of the present invention. Without departing from the design concept of the present invention, any variations and improvements made by those of ordinary skill in the art to the technical solutions of the present invention shall fall within the scope of protection defined by the claims of the present invention.

What is claimed is:

1. An ultra-thin single-crystal metal film, wherein the metal film has a thickness down to a single atomic layer, and a lateral dimension of the ultra-thin single-crystal metal film is greater than 1 μm.

2. The ultra-thin single-crystal metal film according to claim 1, wherein a material of the ultra-thin single-crystal metal film is one of gold, silver, platinum, and copper.

3. The ultra-thin single-crystal metal film according to claim 1, wherein a surface roughness of the ultra-thin single-crystal metal film is less than 1 nm.

4. The ultra-thin single-crystal metal film according to claim 2, wherein a surface roughness of the ultra-thin single-crystal metal film is less than 1 nm.

5. A method for preparing an ultra-thin single-crystal metal film, comprising steps of:
1) preparation of an initial single-crystal metal film 1: preparing a continuous single-crystal metal film on a substrate using epitaxial deposition, or preparing a large-size single-crystal metal sheet on a substrate using chemical synthesis, rinsing an obtained substrate with a single-crystal metal film grown thereon with deionized water, and drying with nitrogen for later use; and
2) preparation of an ultra-thin single-crystal metal film 2: placing the substrate with the single-crystal metal film grown thereon prepared in step 1) into an etching solution 3 for thinning by etching, so that a thickness of the single-crystal metal film gradually decreases with reaction time, after the thickness reaches a target thickness, taking out the substrate, and rinsing with deionized water, and drying with nitrogen to obtain the ultra-thin single-crystal metal film 2.

6. The method for preparing an ultra-thin single-crystal metal film according to claim 5, wherein the etching solution in step 2) is one of a hydrogen peroxide solution, a cysteamine solution, and a cysteamine salt solution.

7. The method for preparing an ultra-thin single-crystal metal film according to claim 5, wherein the reaction time is 5-900 min, and a concentration of the etching solution is 5-500 mM.

8. The method for preparing an ultra-thin single-crystal metal film according to claim 6, wherein the reaction time is 5-900 min, and a concentration of the etching solution is 5-500 mM.

9. The method for preparing an ultra-thin single-crystal metal film according to claim 5, wherein the target thickness in step 2) is 0.2-10 nm.

10. The method for preparing an ultra-thin single-crystal metal film according to claim 5, wherein a thickness of the initial single-crystal metal film 1 in step 1) is greater than 10 nm.

11. The method for preparing an ultra-thin single-crystal metal film according to claim 5, wherein during the thinning by etching process, thickness control of the single-crystal metal film is capable of reaching atomic-level precision.
